(19) United States
(12) Patent Application Publication
(10) Pub. No.: US 2019/0386464 A1
(43) Pub. Date: Dec. 19, 2019

(54) OPTO-ELECTRONIC DEVICE HAVING A BACKSIDE ILLUMINATING VCSEL ARRAY WITH INTEGRATED DIFFRACTIVE OPTICAL ELEMENTS (DOE), DIFFUSER AND/OR LENS

(71) Applicant: OEpic SEMICONDUCTORS, INC., SUNNYVALE, CA (US)

(72) Inventors: YI-CHING PAO, SUNNYVALE, CA (US); MAJID RIAZIAT, SUNNYVALE, CA (US); TA-CHUNG WU, SUNNYVALE, CA (US); WILSON KYI, SUNNYVALE, CA (US); JAMES PAO, SUNNYVALE, CA (US)

(21) Appl. No.: 16/443,529

(22) Filed: Jun. 17, 2019

Related U.S. Application Data
(60) Provisional application No. 62/686,831, filed on Jun. 19, 2018.

(51) Int. Cl. H01S 5/183; H01S 5/42; G02B 27/42

(52) U.S. Cl. CPC H01S 5/18388; G02B 27/4205; H01S 5/423; H01S 5/18361

(57) ABSTRACT

An opto-electronic device has a backside Vertical Cavity Surface Emitting Laser (VCSEL) device. An optical component is formed on a rear surface of the backside VCSEL device.

### RELATED APPLICATIONS

This patent application is related to U.S. Provisional Application No. 62/686,831 filed Jun. 19, 2018, entitled “BACKSIDE ILLUMINATING VCSEL ARRAY WITH INTEGRATED DIFFRACTIVE OPTICAL ELEMENTS (DOE), DIFFUSER AND LENS” in the names of Yi-Ching Pao, Majid Riaziat, Ta-Chung Wu, Wilson Kyi and James Pao, and which is incorporated herein by reference in its entirety. The present patent application claims the benefit under 35 U.S.C § 119(e).

### TECHNICAL FIELD

The present invention generally relates to an opto-electronic device and, more particularly to, an opto-electronic device that has a backside illuminating VCSEL array with integrated diffractive optical elements (DOE), diffuser and/or lens and a method of making the same.

### BACKGROUND

Semiconductor lasers are being used in many imaging applications which require high power illumination such as structured light sources for 3D imaging, Laser Detection and Ranging (LADAR), Time of Flight (TOF) 3D imaging, aviation defense, and fusion research, among others. Vertical Cavity Surface Emitting Lasers (VCSELs), are commonly used in many semiconductor laser applications due to the low power applications and high frequency superiority and manufacturing advantages over other type of semiconductor laser devices.

A VCSEL is a semiconductor micro-laser diode that emits light in a generally cylindrical beam. The beam is emitted vertically from the surface of the substrate on which it is fabricated. Because the beams in VCSELs emit vertically from the surface of the substrate, they can be tested on-wafer, before they are separated into individual devices. This reduces the fabrication cost of the devices. It also allows VCSELs to be built not only in one-dimensional, but also in two-dimensional arrays.

Electronic devices are getting smaller in size and provide more and more features. Thus, integrated circuits (IC), such as VCSEL arrays also need to become smaller and incorporate additional functionality. Presently, VCSEL arrays are getting more and more designed into consumer electronic for 3D sensing and image recognition. Unfortunately, adding additional functionality to VCSEL arrays are generally done after the VCSEL array has been formed.

Therefore, it would be desirable to provide a VCSEL device and method that overcome the above problems. The VCSEL array would integrate on chip a lens, diffuser, and/or Diffractive Optical Element (DOE) to provide a compact and low-cost device.

### SUMMARY

In accordance with one embodiment, an opto-electronic device is disclosed. The opto-electronic device has a backside Vertical Cavity Surface Emitting Laser (VCSEL) device. An optical component is formed on a rear surface of the backside VCSEL device.

In accordance with one embodiment, a method of forming an opto-electronic device is disclosed. The method comprises: forming a backside Vertical Cavity Surface Emitting Laser (VCSEL) device; and forming an optical component on a rear surface of the backside VCSEL device.

In accordance with one embodiment, a method of forming an opto-electronic device is disclosed. The method comprises: forming a backside Vertical Cavity Surface Emitting Laser (VCSEL) device; forming a Diffractive Optical Elements (DOE) on the rear surface of the backside VCSEL device; and forming a lens over the DOE on the rear surface of the backside VCSEL device; wherein forming the DOE on the rear surface of the backside VCSEL device comprises: applying a material on the rear surface of the backside VCSEL device to alter optical characteristics of light emitted from the backside VCSEL device; and forming patterns in the material applied on the rear surface of the backside VCSEL device; wherein forming a lens over the DOE on the rear surface of the backside VCSEL device comprises: applying a lens material on the DOE; and shaping the lens material through one of photolithography or etching.

### BRIEF DESCRIPTION OF THE DRAWINGS

The present application is further detailed with respect to the following drawings. These figures are not intended to limit the scope of the present application but rather illustrate certain attributes thereof. The same reference nu hers will be used throughout the drawings to refer to the same or like parts.

FIG. 1 shows a cross-sectional view of a prior art frontside VCSEL design with a DOE placed in front of the VCSEL device;

FIG. 2 shows a cross-sectional view of a prior art frontside VCSEL design with a DOE placed in front of the VCSEL device;

FIGS. 3A-3B shows a perspective view of a prior art diffractive optical element (DOE);

FIG. 4 is a cross-sectional view of an exemplary embodiment of a backside illuminating VCSEL device in accordance with one aspect of the present application;

FIGS. 5A-5E are cross-sectional views of an exemplary embodiment of an opto-electronic device in accordance with one aspect of the present application; and

FIG. 6A-6E are cross-sectional views of an exemplary embodiment of an opto-electronic device in accordance with one aspect of the present application.

### DESCRIPTION OF THE APPLICATION

The description set forth below in connection with the appended drawings is intended as a description of presently preferred embodiments of the disclosure and is not intended to represent the only forms in which the present disclosure may be constructed and/or utilized. The description sets forth the functions and the sequence of steps for constructing and operating the disclosure in connection with the illustrated embodiments. It is to be understood, however, that the same or equivalent functions and sequences may be accomplished by different embodiments that are also intended to be encompassed within the spirit and scope of this disclosure.

Embodiments of the exemplary opto-electronic device and method of forming the same disclose a backside illuminating VCSEL array having one or more on chip integrate lens, diffuser, and/or Diffractive Optical Element (DOE). The opto-electronic device having a backside illuminating VCSEL array having one or care on chip integrate lens, diffuser, and/or DOE offers multiple advantages over the prior art designs namely: (1) integrated lens, diffuser, and/or DOE on the backside of the VCSEL array, (2) leveraging on the substrate thickness (from 25 um to 150 um) as an optical design parameter, (3) using standard semiconductor lithography and etch process to form lens, diffuser, and/or DOE on the back of the VCSEL, and (4) single flip chip configuration. In accordance with one embodiment, a preferred wavelength of the current invention of opto-electronic device having a backside illuminating VCSEL array having one or more on chip integrate lens, diffuser, and/or DOE may be 940 nm or longer for 3D sensing applications, other integrated high-power applicable wavelengths may be 850 nm, 980 nm, and 1310-1550 nm as examples.

In accordance with the present embodiment, the integrated photo-lithographically defined and semiconductor process formed lens, diffuser, and/or DOE may be formed on the back of the substrate when a backside illuminating VCSEL array is implemented. Presently, 3D sensing applications require structure light creation by projecting the VCSEL laser light through the DOE/diffuser/lens. However, the prior art requires separated and individual VCSEL device to be formed and then the DOE attached through some optical arrangements and alignments which is not only bulky, and low yield, but also high cost. The current invention, based on the framework of a backside illuminating VCSEL array, opens up a new approach of integrating photo-lithographically defined lens, diffuser, and/or DOE onto the backside of the VCSEL substrate, making all these elements integrated onto the same chip possible which dramatically reduces the size of the overall optical assembly and packaging arrangement and at the same time increases the overall yield and lowers the cost. This is the same for 3D sensing with TOF where only a lens is required without a DOE.

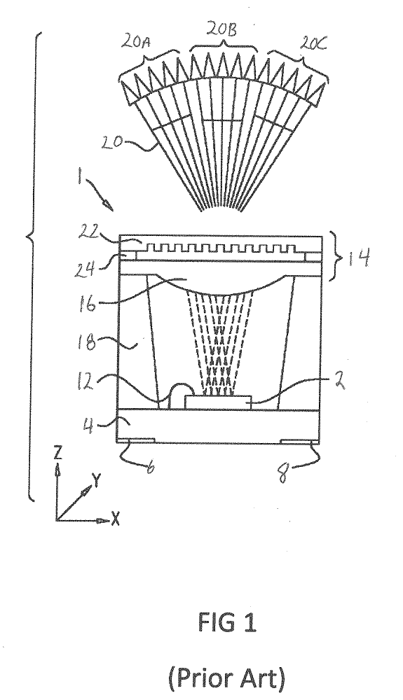

FIG. 1 may show a typical prior art design of an optical device 1 which uses a VCSEL array with structure light outputs. In this embodiment, the optical device 1 has a VCSEL die 2. The VCSEL die 2 is typically tested at wafer level, and is then diced and mounted on a suitable substrate 4 having electrical connections 6, 8, 12. Optics 14, including a cylindrical projection lens 16, may be mounted over the VCSEL die on spacers 18. The lens 16 collects and projects an output beam 20 of the VCSEL emitters. For temperature stability, a glass lens may be used. A diffractive optical element (DOE) 22, supported by thin spacers 24, creates multiple replicas 20A, 20B, 20C of the pattern of the lines of the VCSEL array, fanning out over a predefined angular range.

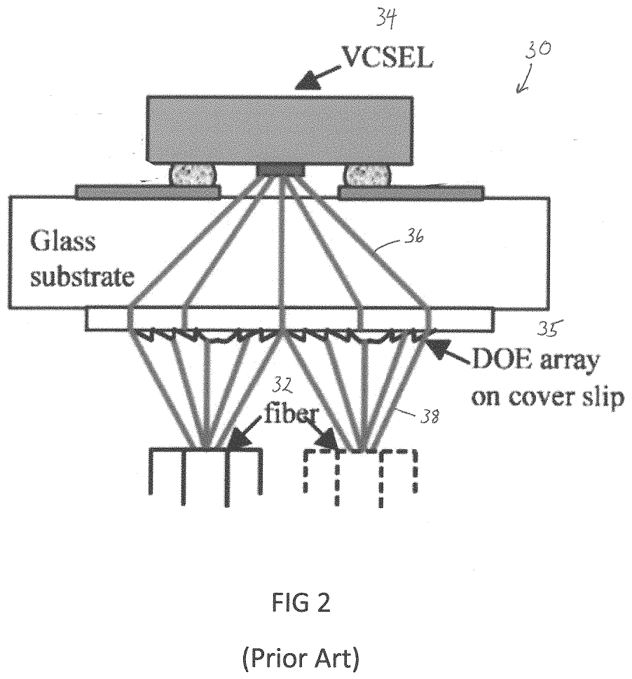

In other application such as fiber communication, similar optical arrangements are feasible to split and focus the VCSEL laser beam into a given pattern as directed by the DOE design. FIG. 2 shows a typical optical module 30 arrangement for splitting the VCSEL laser beam into two optical fibers 32. In this embodiment, the VCSEL chip 34 is flip-chip mounted but it remains to be a frontside illuminating VCSEL as the laser light 36 does not go through the VCSEL semiconductor substrate as a backside illuminating VCSEL does. Furthermore, the VCSEL chip 34 alignment to the aperture of the DOE 35 becomes critical in producing the precise beam profile 38 as all optical parts are mechanically separated but assembled through chip mount and not lithographically integrated.

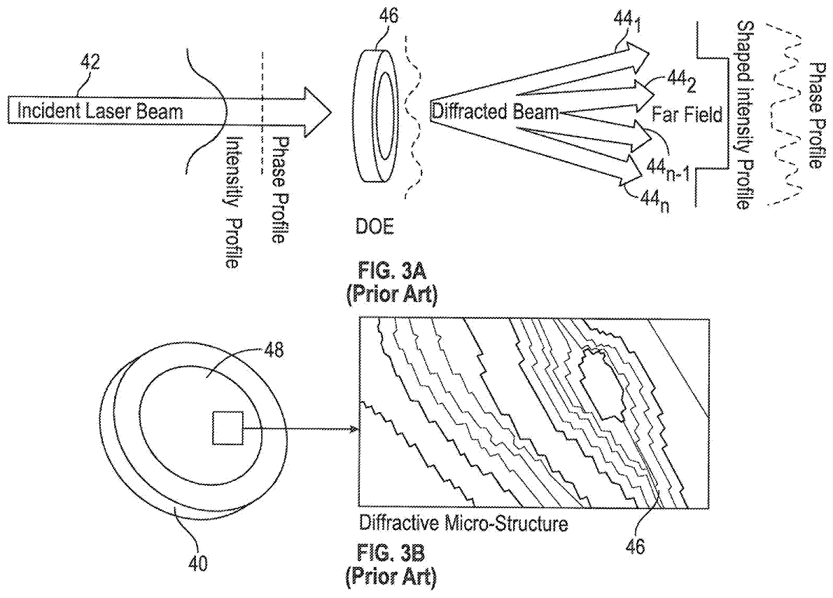

Referring to FIG. 3A-3B a DOE structure 40 may be disclosed. The DOE structure 40 is a single optical element that is able to take a single input beam 42 and generate N output beams 44₁-44ₙ. Each output beam 44₁-44ₙ may retain the same optical characteristics as the input beam 42, such as size, polarization and phase.

As shown more clearly in FIG. 3B, the DOE structure 40 may have etched patterns 46 formed onto a transparent film or substrate 48 such as fused silica. When the input beam 42 goes through the DOE structure 40, under the diffractive optical interference, a desired far field optical pattern is hence generated such as that shown in FIG. 3A, N output beams 44₁-44ₙ. It should be noted that other output patterns may be generated other than that shown in FIG. 3A. The output pattern shown in FIG. 3A is shown just as one example.

All prior art VCSEL arrays are designed for front-side illuminating, thus the backside of the VCSEL array is used only for contact metal and heat sink purpose as the laser lights do not go through the substrate. In a backside illuminating VCSEL, where the laser lights go through the substrate, the backside of the VCSEL opens up an opportunity to form on chip integration of DOE, diffuser, and/or lens on the VCSEL through various semiconductor lithography and processes.

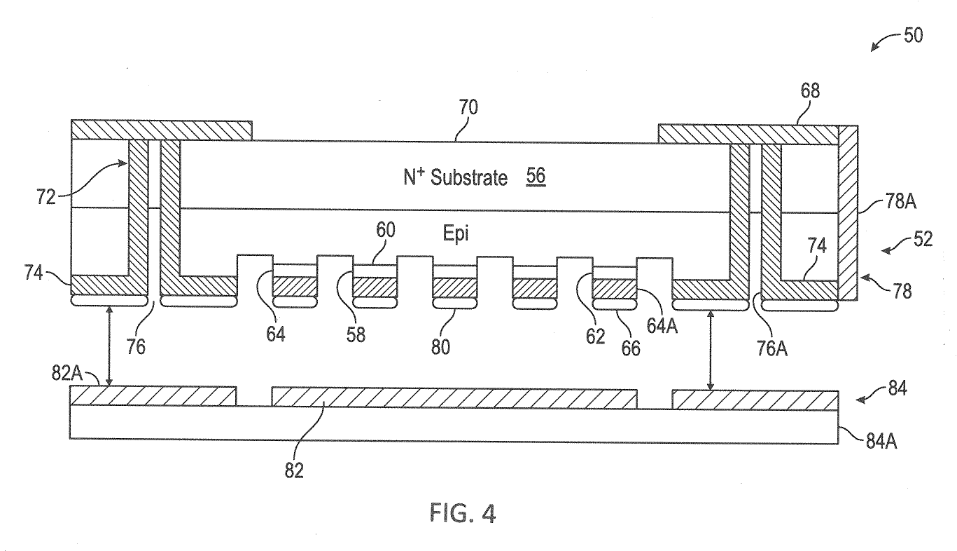

The current invention is intended to integrate not only DOE, but also diffuser and/or lens or in any combinations of these optical components, onto a backside illuminating VCSEL through standard lithography and semiconductor processes. Referring to FIG. 4, a backside illuminating VCSEL package 50 (hereinafter VCSEL package 50) may be shown. The VCSEL package 50 is described in co-pending patent application entitled “FLIP CHIP BACKSIDE EMITTING VCSEL PACKAGE” in the name of Yi-Ching Pao, filed Jan. 3, 2019, having U.S. Ser. No. 16/239,083 and which is incorporated herewith in its entirety.

The VCSEL package 50 may have a backside emitting VCSEL array 52 (hereinafter VCSEL array 52). The VCSEL array 52 may be formed in a manner described in co-pending patent application entitled “PILLAR CONFINED BACKSIDE ILLUMINATING VCSEL” in the name of Yi-Ching Pao, Majid Riaziat, Ta-Cluing Wu, Wilson Kyi and James Pao, filed Dec. 4, 2018, having Ser. No. 16/208,958, and which is incorporated herein by reference in its entirety.

The VCSEL array 52 is formed on a substrate 56. The substrate 56 may be gallium arsenide (GaAs) substrate 56 or similar material. In accordance with one embodiment, the substrate 56 may be an N+ substrate or a semi-insulation substrate.

A pair of Distributed Braggs Reflectors (DBR) 58 and 60 may be formed on the substrate 56 and runs parallel to the substrate 56. The DBRs 58 and 60 may be formed of a plurality of layers. The DBRs 58 and 60 may be formed by disposing multiple layers of alternating materials with varying optical impedances. In general, the multiple alternate between high and low optical impedances. An active region 62 may be formed between the pair of DBRs 58 and 60. The active region 62 may be formed of one or more quantum wells for laser light generation.

A plurality of pillars 64 may then be formed. In the present embodiment, a highly directional ICP (Inductive Coupled Plasma) reactive ion etcher (RIE) may be used to etch highly anisotropic pillars 64. By using ICP-RIE, the pillars 64 may have a cylinder type of cross-sectional profile having close to straight side walls. In accordance with one embodiment, the pillars 64 may have a profile in the 5-50 um diameter range. Etching by using ICP-RIE is important since if wet chemical isotropic etchant is used, the side walls of the pillars 64 will be tapered which will present issues when small diameter VCSELs are to be fabricated. Thus, the pillars 64 should be etched by ICP-RIE with an anisotropic straight wall profile.

A metal contact 66 may then be deposited and cover the top of each of the pillars 64. The metal contact 66 does not have to be in a ring configuration to emit laser light therethrough. In accordance with one embodiment, the metal contact 66 may be use as the pillar ICP-RIE etch mask so there will be no need to deposit the top metal contact after the ICP-RIE pillar etch is performed.

After the metal contact 66 is formed, the wafer upon which the VCSEL array 52 is formed upon may be turned around to form a metal contact 68. The metal contact 68 may be formed with an opening 70 to allow the laser light to be emitted from the back of the VCSEL array 52. The opening 70 may be aligned with the pillars 64 to allow the laser light to be emitted from the back of the VCSEL array 52.

Electrical connections 72 may be formed between the metal contact 68 and a backside of the substrate 56. Alternatively, or in addition to, the electrical connections 72 may be formed between the metal contact 68 and metal contacts 74 formed on the backside of the substrate 56 and around an outer perimeter of the pillars 64. The electrical connections 72 may be one or more vias 76 formed on around an outer perimeter of the VCSEL array 52, wrap around connections 78, or the like. If vias 76 are used, the vias 76 may have a metal coating 76A to form an electrical connection. The wrap around connection 78 may use a metal connector 78A which is applied to and conforms to the side of the VCSEL array 52. The electrical connections 72 eliminates the use of any bond wires and bond pads thereby reducing the footprint due of the VCSEL package 50. The footprint due of the VCSEL package 50 may now be approximately the same as the VCSEL array 52.

To flip-chip mount the VCSEL array 52 with a one-step re-flow assembly process, solder tips 80 may be applied to the metal contacts 66 on every pillar 64 and to a bottom surface of the metal contacts 74. It is important that the solder tips 80 are plated and formed on the top of each pillar 64 to ensure good thermal contact of each and every pillar 64 within the VCSEL array 52, and to avoid any air voids formed underneath, which may cause uneven thermal contact and create localized heated spots.

In accordance with one embodiment, the solder tips 80 may be done by electric-chemical plating a thin layer of solder 80 such as Au—Sn on top of the metal contact 66 of each pillar 64 and the metal contacts 74. The wafer upon which the VCSEL array 52 is formed upon may be turned upside down so that the solder tips 88 meets and join metal contacts 82 of a package 84. The package 84 may have a heat sinking substrate 84A to extract the heat generated by the VCSEL array 52 when high power applications are intended. The heat sinking substrate 84A can be either ceramic or PCB (FR4 or FR5 as examples) based where metal pads and electrical connections are formed by photolithography, plating, and/or chemical etching processes. In accordance with one embodiment, the solder tips 80 meets and joins the metal contacts 82 through a furnace re-flow process.

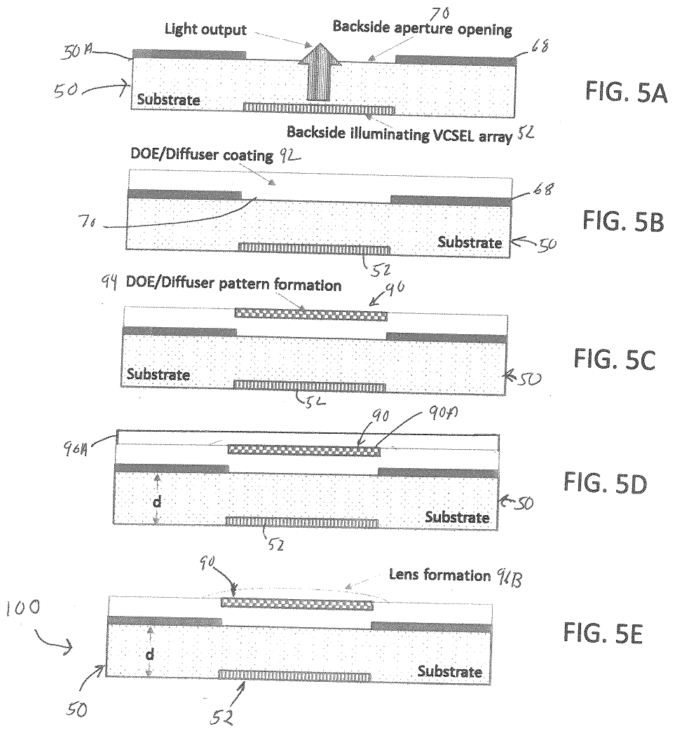

Referring now to FIG. 5A-5D, one embodiment of an opto-electronic device 100 leveraging on the VCSEL package 50 an integrated DOE, diffuser, and lens on the back of the VCSEL array 52 may be disclosed. FIG. 5A shows the VCSEL package 50 as shown in FIG. 4 prior to attaching the package 84. The optical components may then be formed on a rear surface 50A of the VCSEL package 50.

In FIG. 5B, a DOE 90 may first be formed. The DOE 90 may be formed through semiconductor processes of spinning/coating of polymers such as SiNx, dielectric films, or even fused silica films 92 (hereinafter coating 92) on the rear surface 50A of the VCSEL package 50. The coating 92 is able to alter optical characteristics of a light 102 emitted from the VCSEL array 52 and generate a desired far field optical pattern. The key is these spin-on or deposited layer materials (i.e. coating 92) should be compatible to standard semiconductor lithography and etch (dry or wet) processes. The coating 92 may be applied over the metal contact 68 and the opening 70.

In FIG. 5C, patterns 94 may be formed in the coating 92. The patterns 94 may be formed through lithography process such as photolithography. Photolithography uses light to transfer a geometric pattern from a photomask to a photosensitive chemical photoresist on the coating 92. A series of chemical treatments then either etches the exposure pattern into the coating 92 or enables deposition of a new material into the desired pattern 94. The pattern 94 formed is able to alter optical characteristics of a light 102 emitted from the VCSEL array 52 and generate a desired far field optical pattern.

Referring to FIG. 5D, a lens 96B may then be formed by itself or over an area of the DOE 90 where the pattern 94 may be formed. The lens 96B may be formed in a similar manner as the DOE 90. The lens 96B may be formed through semiconductor processes of spinning/coating of polymers such as SiNx, dielectric films, or even fused silica films 96A (hereinafter coating 96A) by itself or over a surface 90A of the DOE 90. The key is these spin-on or deposited layer materials should be compatible to standard semiconductor lithography and etch (dry or wet) processes. The lens 96B may then be shaped through a photolithographic and etching techniques as shown in FIG. 5E.

It should be noted that the above steps for forming the DOE 90 and/or lens 96B may require multiple coatings and etching and processing until the desired optical structures and arrangements are formed on the back of the backside illuminating VCSEL package 50.

The optical alignment of the DOE 90 and/or lens 96 to the VCSEL package 50 is formed by direct integration onto the VCSEL package 50 thus providing a self-aligned arrangement without any yield losing mechanical and assembly alignment.

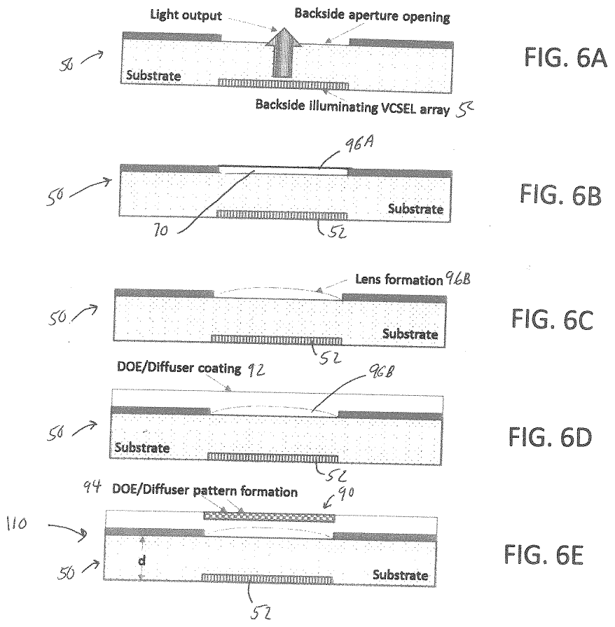

Other configurations than that shown in FIG. 5A-5E may be formed. FIG. 6A-6E shows a configuration where the sequence of forming the DOE, diffuser, and/or lens may be switched to obtain or to optimize different optical arrangement to create the desired structure light patterns.

Referring now to FIG. 6A-6D, one embodiment of an opto-electronic device 110 leveraging on the VCSEL package 50 an integrated DOE, diffuser, and lens on the back of the VCSEL array 52 may be disclosed. FIG. 6A shows the VCSEL package 50 as shown in FIG. 4 prior to attaching the package 84. The optical components may then be formed on a rear surface 50A of the VCSEL package 50.

In FIG. 6B, a lens 96B may then be formed in the opening 70. The lens 96B may be formed through semiconductor processes of spinning/coating of polymers such as SiNx, dielectric films, or even fused silica films 96A (hereinafter coating 96A) over the opening 70. The key is these spin-on or deposited layer materials should be compatible to standard semiconductor lithography and etch (dry or wet) processes. The lens 96B may then be shaped through a photolithographic and etching techniques as shown in FIG. 6C.

Referring to FIG. 6D, the DOE 90 may first be formed over the lens 96B. The DOE 90 may be formed through semiconductor processes of spinning/coating of polymers such as SiNx, dielectric films, or even fused silica films 92 (hereinafter coating 92) over the lens 96 on the backside of the VCSEL package 50. The key is these spin-on or deposited layer materials should be compatible to standard semiconductor lithography and etch (dry or wet) processes.

In FIG. 6E, patterns 94 may be formed in the coating 92. The patterns 94 may be formed through lithography process such as photolithography. Photolithography uses light to transfer a geometric pattern from a photomask to a photosensitive chemical photoresist on the coating 92. A series of chemical treatments then either etches the exposure pattern into the coating 92 or enables deposition of a new material into the desired pattern.

It should be noted that the above steps for forming the DOE 90 and lens 96B may require multiple coatings and etching and processing until the desired optical structures and arrangements are formed on the rear surface 50A of the VCSEL package 50.

The optical alignment of the DOE 90 and lens 96B to the VCSEL package 50 is formed by direct integration onto the VCSEL package 50 thus providing a self-aligned arrangement without any yield losing mechanical and assembly alignment.

While embodiments of the disclosure have been described in terms of various specific embodiments, those skilled in the art will recognize that the embodiments of the disclosure may be practiced with modifications within the spirit and scope of the claims

What is claimed is:

1. An opto-electronic device comprising:
a backside Vertical Cavity Surface Emitting Laser (VCSEL) device; and
an optical component formed on a rear surface of the backside VCSEL device.

2. The opto-electronic device of claim 1, wherein the optical component comprises a Diffractive Optical Elements (DOE) formed on the rear surface of the backside VCSEL device.

3. The opto-electronic device of claim 2, comprising a lens formed on the DOE.

4. The opto-electronic device of claim 1, wherein the optical component comprises a lens formed on the rear surface of the backside VCSEL device.

5. The opto-electronic device of claim 4, comprising a DOE formed on the lens.

6. The opto-electronic device of claim 1, wherein the backside VCSEL device comprises:
a substrate;
a first mirror device formed on the substrate;
an active region formed on the first mirror device;
a second mirror device formed on the active region;
a pillar formed by directional Inductive Coupled Plasma-Reactive Ion Etcher (ICP-RIE), the pillar exposing a portion of the first mirror device, the active region and the second mirror device;
a first metal contact formed over a top section of the pillar;
a second metal contact formed on the substrate; and
an opening formed in the second metal contact and aligned with the pillar.

7. A method of forming an opto-electronic device, comprising:
forming a backside Vertical Cavity Surface Emitting Laser (VCSEL) device; and
forming an optical component on a rear surface of the backside VCSEL device.

8. The method of claim 7, wherein forming an optical component on a rear surface of the backside VCSEL device comprises forming a Diffractive Optical Elements (DOE) on the rear surface of the backside VCSEL device.

9. The method of claim 8, comprising forming a lens over the DOE on the rear surface of the backside VCSEL device.

10. The method of claim 8, wherein forming the DOE on the rear surface of the backside VCSEL device comprises:
applying a material on the rear surface of the backside VCSEL device to alter optical characteristics of light emitted from the backside VCSEL device; and
forming patterns in the material applied on the rear surface of the backside VCSEL device.

11. The method of claim 10, wherein applying a material on the rear surface of the backside VCSEL device comprises one of: spinning/coating of polymers, applying a dielectric film, or applying fused silica films on the rear surface of the backside VCSEL device.

12. The method of claim 10, wherein forming patterns in the material applied on the rear surface of the backside VCSEL device comprises forming patterns in the material through one of photolithography or etching.

13. The method of claim 9, wherein forming a lens over the DOE on the rear surface of the backside VCSEL device comprises:
applying a lens material on the DOE; and
shaping the lens material.

14. The method of claim 13, wherein shaping the lens material comprises shaping the lens material through one of photolithography or etching.

15. The method of claim 7, wherein forming an optical component on a rear surface of the backside VCSEL device comprises forming a lens on the rear surface of the backside VCSEL device.

16. The method of claim 15, comprising forming a Diffractive Optical Elements (DOE) on the lens.

17. The method of claim 7, where forming a backside Vertical Cavity Surface Emitting Laser (VCSEL) device comprises:
forming a first mirror device on a substrate;
forming an active region on the first mirror device;
forming a second mirror device on the active region;
forming a pillar by directional Inductive Coupled Plasma-Reactive Ion Etcher (ICP-RIE), the pillar exposing a portion of the first mirror device, the active region and the second mirror device;
applying a first metal contact over a top section of the pillar; and
applying a second metal contact on the substrate, wherein an opening is formed in the second metal contact, the opening aligned with the pillar.

18. A method of forming an opto-electronic device, comprising:
forming a backside Vertical Cavity Surface Emitting Laser (VCSEL) device;
forming a Diffractive Optical Elements (DOE) on the rear surface of the backside VCSEL device; and
forming a lens over the DOE on the rear surface of the backside VCSEL device;
wherein forming the DOE on the rear surface of the backside VCSEL device comprises:
applying a material on the rear surface of the backside VCSEL device to alter optical characteristics of light emitted from the backside VCSEL device; and
forming patterns in the material applied on the rear surface of the backside VCSEL device;
wherein forming a lens over the DOE on the rear surface of the backside VCSEL device comprises:
applying a lens material on the DOE; and
shaping the lens material through one of photolithography or etching.

19. The method of claim 18, wherein applying a material on the rear surface of the backside VCSEL device comprises one of: spinning/coating of polymers, applying a dielectric film, or applying fused silica films on the rear surface of the backside VCSEL device.

20. The method of claim 18, wherein forming patterns in the material applied on the rear surface of the backside VCSEL device comprises forming patterns in the material through one of photolithography or etching.

21. The method of claim 18, where forming a backside Vertical Cavity Surface Emitting Laser (VCSEL) device comprises:
forming a first mirror device on a substrate;
forming an active region on the first mirror device;
forming a second mirror device on the active region;
forming a pillar by directional Inductive Coupled Plasma-Reactive Ion Etcher (ICP-RIE), the pillar exposing a portion of the first mirror device, the active region and the second mirror device;
applying a first metal contact over a top section of the pillar; and
applying a second metal contact on the substrate, wherein an opening is formed in the second metal contact, the opening aligned with the pillar.
